(19) United States
(12) Patent Application Publication
(10) Pub. No.: US 2022/0406676 A1
(43) Pub. Date: Dec. 22, 2022

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ping-Yin Hsieh, Hsinchu (TW); Pu Wang, Hsinchu City (TW); Tsung-Fu Tsai, Changhua County (TW); Li-Hui Cheng, New Taipei City (TW); Szu-Wei Lu, Hsinchu City (TW)

(73) Assignee: Taiwan Semiconductor Manufacturing Company, Ltd., Hsinchu (TW)

(21) Appl. No.: 17/351,251

(22) Filed: Jun. 18, 2021

(51) Int. Cl. H01L 23/367; H01L 23/42; H01L 23/373; H01L 21/52; H01L 25/16

(52) U.S. Cl. CPC H01L 23/367; H01L 23/42; H01L 23/3736; H01L 21/52; H01L 25/165

(57) ABSTRACT

A semiconductor device includes a substrate, a package structure, a thermal interface material (TIM) layer, and a lid structure. The package structure is disposed on the substrate. The TIM layer is disposed on the package structure. The TIM layer includes a liquid state metal material. The lid structure is disposed on the substrate and the TIM layer. The lid structure includes a trench facing the package structure. At least a portion of the TIM layer is located in the trench.

### BACKGROUND

The semiconductor integrated circuit (IC) industry has experienced rapid growth. Over the course of this growth, functional density of the devices has generally increased by the device feature size. This scaling down process generally provides benefits by increasing production efficiency, lower costs, and/or improving performance. Such scaling down has also increased the complexities of processing and manufacturing IC. For these advances to be realized, developments in IC fabrication are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1H are schematic cross-sectional views illustrating a manufacturing process of a semiconductor die in accordance with some embodiments of the disclosure.

FIG. 2A to FIG. 2C are schematic cross-sectional views illustrating a manufacturing process of a package structure in accordance with some embodiments of the disclosure.

FIG. 3A to FIG. 3E are schematic cross-sectional views illustrating a manufacturing process of a semiconductor device in accordance with some embodiments of the disclosure.

FIG. 4 is a schematic bottom view of the lid structure in FIG. 3D.

FIG. 5A is a schematic enlarged view illustrating a region in FIG. 3D in accordance with some embodiments of the disclosure.

FIG. 5B is a schematic enlarged view illustrating a region in FIG. 3D in accordance with some alternative embodiments of the disclosure.

FIG. 5C is a schematic enlarged view illustrating a region in FIG. 3D in accordance with some alternative embodiments of the disclosure.

FIG. 6 is a schematic cross-sectional view illustrating a semiconductor device in accordance with some alternative embodiments of the disclosure.

FIG. 7 is a schematic bottom view of the lid structure in FIG. 6.

FIG. 8 is a schematic cross-sectional view illustrating a semiconductor device in accordance with some alternative embodiments of the disclosure.

FIG. 9 is a schematic bottom view of the lid structure in FIG. 8.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

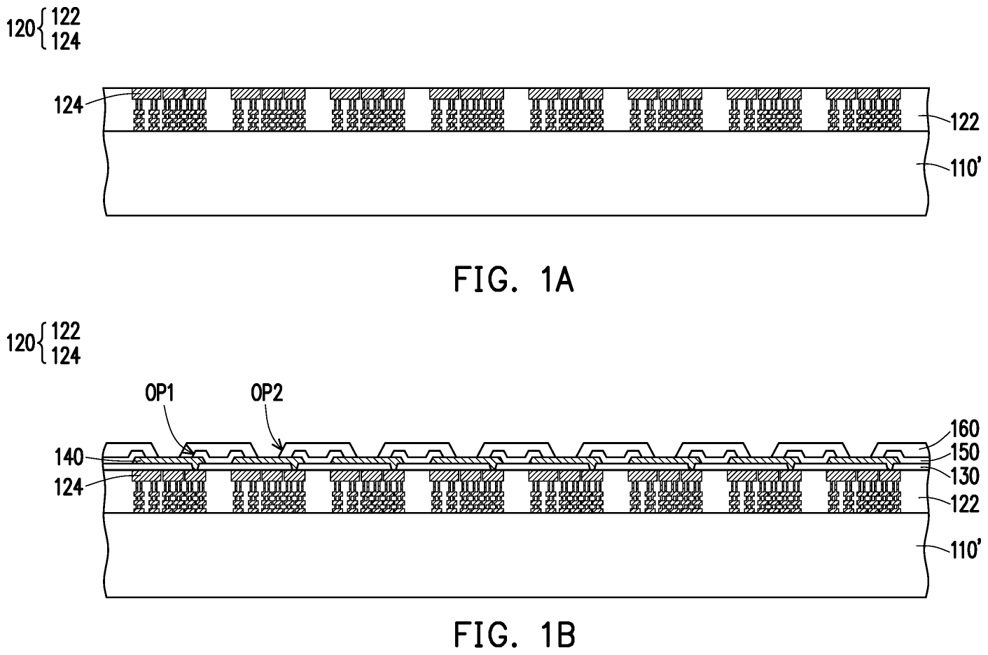

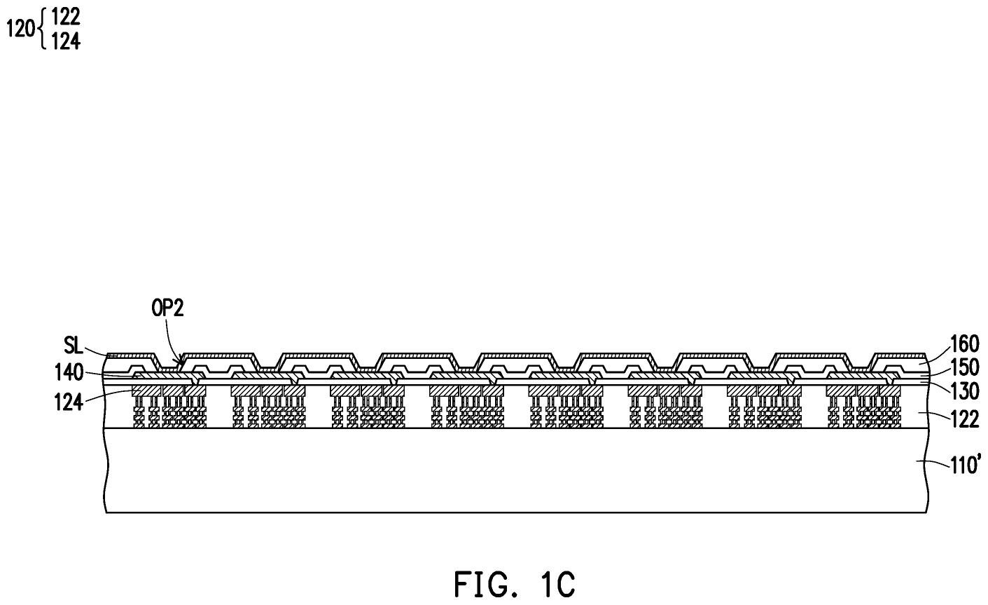

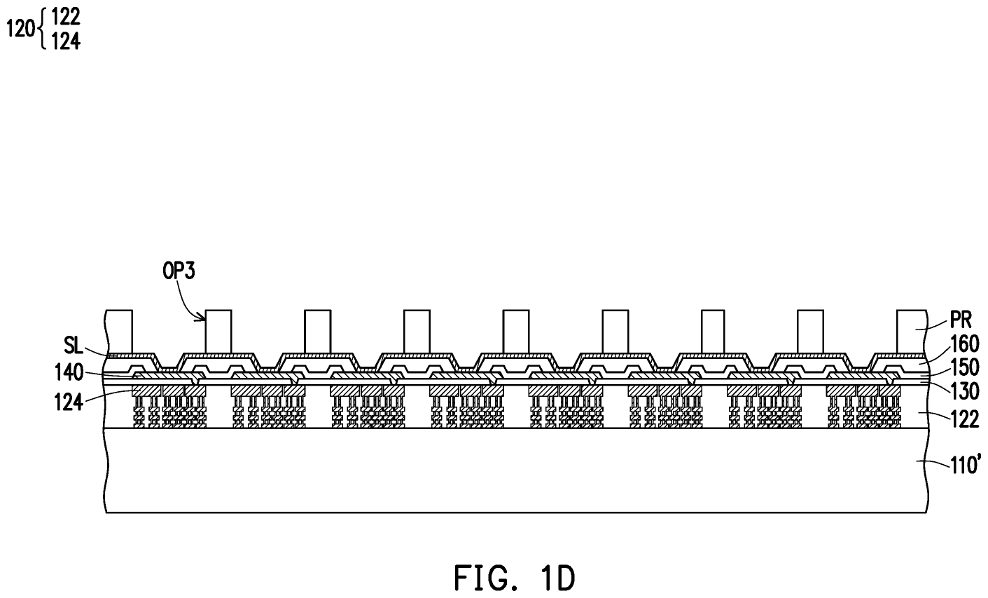

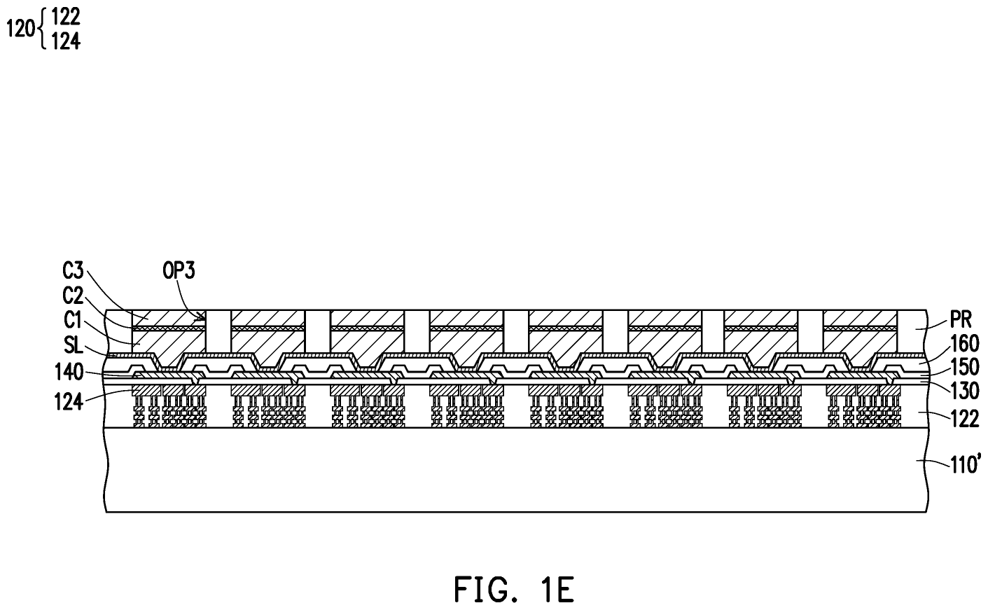

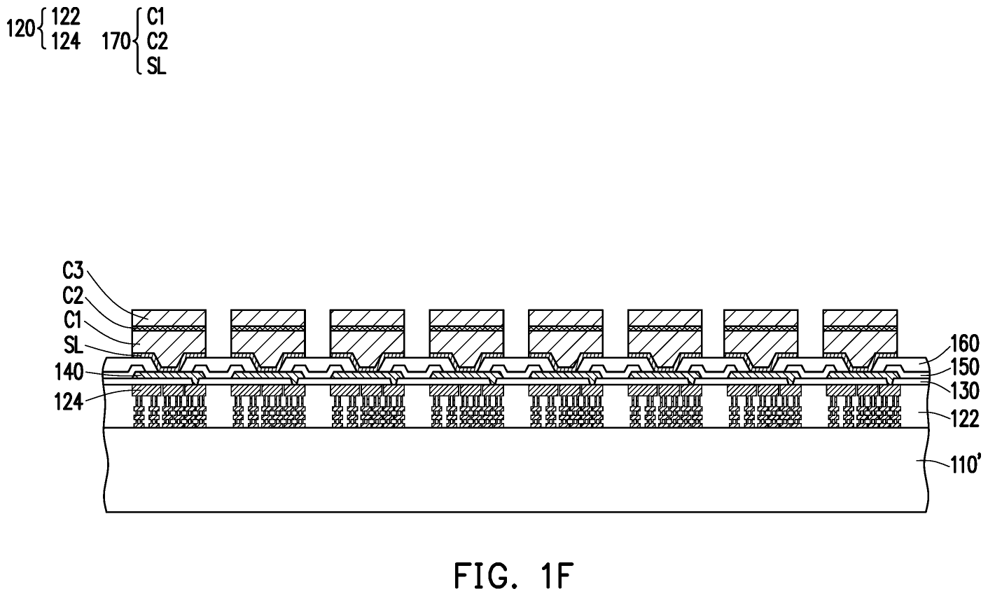

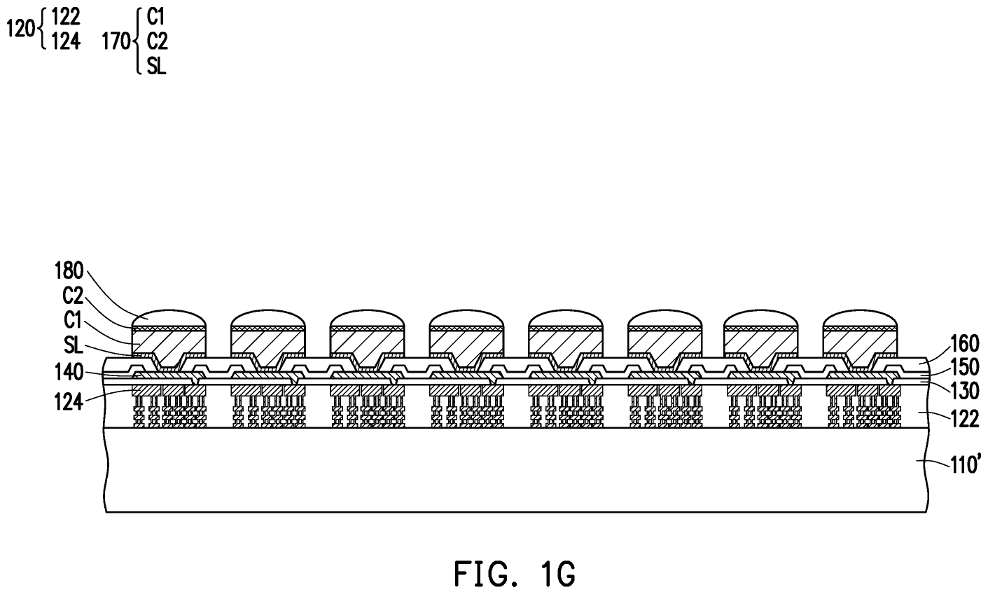

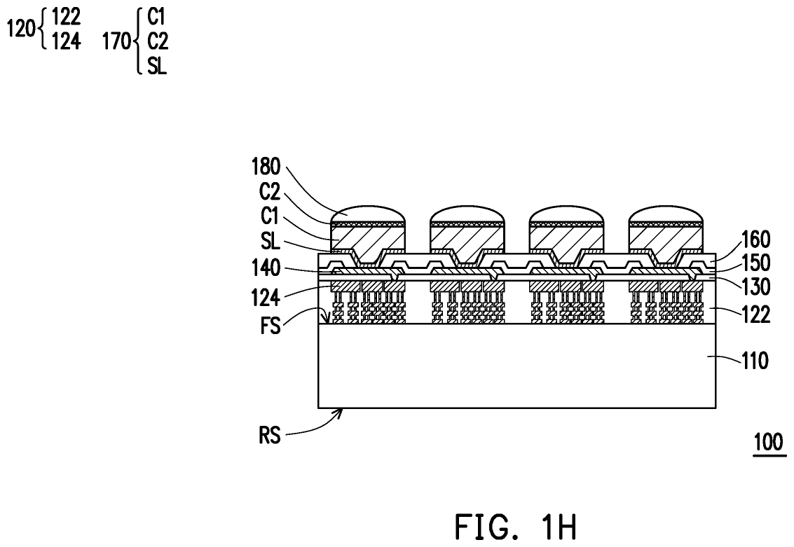

FIG. 1A to FIG. 1H are schematic cross-sectional views illustrating a manufacturing process of a semiconductor die 100 in accordance with some embodiments of the disclosure. Referring to FIG. 1A, a semiconductor wafer 110′ is provided. In some embodiments, the semiconductor wafer 110′ is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor wafer 110′ has active components (e.g., transistors or the like) and passive components (e.g., resistors, capacitors, inductors, or the like) formed therein.

In some embodiments, an interconnection structure 120 is formed on the semiconductor wafer 110′. In some embodiments, the interconnection structure 120 includes an inter-dielectric layer 122 and a plurality of patterned conductive layers 124. For simplicity, the inter-dielectric layer 122 is illustrated as a bulky layer in FIG. 1A, but it should be understood that the inter-dielectric layer 122 may be constituted by multiple dielectric layers. The patterned conductive layers 124 and the dielectric layers of the inter-dielectric layer 122 are stacked alternately. In some embodiments, two vertically adjacent patterned conductive layers 124 are electrically connected to each other through conductive vias sandwiched therebetween.

In some embodiments, a material of the inter-dielectric layer 122 includes polyimide, epoxy resin, acrylic resin, phenol resin, benzocyclobutene (BCB), polybenzoxazole (PBO), or other suitable polymer-based dielectric materials. The inter-dielectric layer 122 may be formed by suitable fabrication techniques, such as spin-on coating, chemical vapor deposition (CVD), plasma-enhanced chemical vapor deposition (PECVD), or the like. In some embodiments, a material of the patterned conductive layers 124 includes aluminum, titanium, copper, nickel, tungsten, and/or alloys thereof. The patterned conductive layers 124 may be formed by electroplating, deposition, and/or photolithography and etching. It should be noted that the number of the patterned conductive layers 124 and the dielectric layers in the inter-dielectric layer 122 shown in FIG. 1A is merely an exemplary illustration, and the disclosure is not limited. In some alternative embodiments, the number of the patterned conductive layers 124 and the dielectric layers in the inter-dielectric layer 122 may be adjusted depending on the routing requirements.

Referring to FIG. 1B, a dielectric layer 130 is formed over the interconnection structure 120. In some embodiments, a material of the dielectric layer 130 includes polyimide, epoxy resin, acrylic resin, phenol resin, BCB, PBO, or any other suitable polymer-based dielectric material. The dielectric layer 130 may be formed by suitable fabrication techniques, such as spin-on coating, CVD, PECVD, or the like. In some embodiments, a plurality of openings is formed in the dielectric layer 130 to expose portions of the topmost patterned conductive layer 124. After the openings are formed, a plurality of conductive pads 140 is formed over the dielectric layer 130. For example, the conductive pads 140 are formed over the semiconductor wafer 110′ and the interconnection structure 120 such that the interconnection structure 120 is located between the semiconductor wafer 110′ and the conductive pads 140. In some embodiments, the locations of the conductive pads 140 correspond to the locations of the openings of the dielectric layer 130. For example, the conductive pads 140 extend into the openings of the dielectric layer 130 to render electrical connection between the conductive pads 140 and portions of the interconnection structure 120 (i.e. the patterned conductive layer 124). In some embodiments, the conductive pads 140 are aluminum pads, copper pads, or other suitable metal pads. The number and the shape of the conductive pads 140 may be selected based on demand.

After the conductive pads 140 are distributed over the dielectric layer 130, a passivation layer 150 and a post-passivation layer 160 are sequentially formed over the dielectric layer 130 and the conductive pads 140. In some embodiments, the passivation layer 150 has a plurality of contact openings OP1 which partially exposes the conductive pads 140. In some embodiments, the passivation layer 150 is a silicon oxide layer, a silicon nitride layer, a silicon oxy-nitride layer, or a dielectric layer formed by other suitable dielectric materials. As illustrated in FIG. 1B, the post-passivation layer 160 covers the passivation layer 150 and has a plurality of contact openings OP2. The conductive pads 140 are partially exposed by the contact openings OP2 of the post-passivation layer 160. In some embodiments, the post-passivation layer 160 is a polyimide layer, a PBO layer, or a dielectric layer formed by other suitable polymers. It should be noted that the post-passivation layer 160 may be optional in some embodiments.

Referring to FIG. 1C, after forming the post-passivation layer 160, a seed layer SL is conformally formed on the post-passivation layer 160. For example, at least a portion of the seed layer SL extends into the contact openings OP2 of the passivation layer 160 to be in physical with the conductive pads 140. The seed layer SL may be formed through a sputtering process, a physical vapor deposition (PVD) process, or the like. In some embodiments, the seed layer SL is constituted by two sub-layers (not shown). The first sub-layer may include titanium, titanium nitride, tantalum, tantalum nitride, other suitable materials, or a combination thereof. On the other hand, the second sub-layer may include copper, copper alloys, or other suitable choice of materials.

Referring to FIG. 1D, a patterned photoresist layer PR is formed over the seed layer SL. In some embodiments, the patterned photoresist layer PR is made of a photosensitive material. In some embodiments, the patterned photoresist layer PR has a plurality of openings OP3 partially exposing the seed layer SL above the contact pads 140. For example, the openings OP3 expose the seed layer SL located directly above the contact pads 140.

Referring to FIG. 1E, a first conductive layer C1, a second conductive layer C2, and a third conductive layer C3 are sequentially deposited onto the exposed seed layer SL. For example, the first conductive layer C1, the second conductive layer C2, and the third conductive layer C3 are filled into the openings OP3 of the patterned photoresist layer PR. In some embodiments, the first conductive layer C1, the second conductive layer C2, and the third conductive layer C3 are formed through the same technique. However, the disclosure is not limited thereto. In some alternative embodiments, the first conductive layer C1, the second conductive layer C2, and the third conductive layer C3 may be formed by different techniques. In some embodiments, the first conductive layer C1, the second conductive layer C2, and the third conductive layer C3 are formed through a plating process. The plating process is, for example, an electro-plating process, an electroless-plating process, an immersion plating process, or the like. In some embodiments, materials of the first conductive layer C1, the second conductive layer C2, and the third conductive layer C3 are different. For example, the first conductive layer C1 is made of aluminum, titanium, copper, tungsten, and/or alloys thereof. On the other hand, the second conductive layer C2 is made of nickel. Moreover, the third conductive layer C3 is made of solder. In some embodiments, a thickness of the first conductive layer C1 is greater than a thickness of the second conductive layer C2 and a thickness of the third conductive layer C3. On the other hand, the thickness of third conductive layer C3 is greater than the thickness of the second conductive layer C2.

Referring to FIG. 1E and FIG. 1F, the patterned photoresist layer PR is removed. The patterned photoresist layer PR may be removed through an etching process, a stripping process, an ashing process, a combination thereof, or the like. Thereafter, by using the first conductive layer C1, the second conductive layer C2, and the third conductive layer C3 as hard masks, the seed layer SL that is uncovered by the first conductive layer C1, the second conductive layer C2, and the third conductive layer C3 is removed. In some embodiments, portions of the seed layer SL are removed through an etching process. After removal of portions of the seed layer SL, the remaining seed layer SL is located directly underneath the first conductive layer C1. That is, the seed layer SL is sandwiched between the contact pads 140 and the first conductive layer C1. In some embodiments, the remaining seed layer SL, the first conductive layer C1, and the second conductive layer C2 are collectively referred to as conductive posts 170.

Referring to FIG. 1F and FIG. 1G, a reflow process is performed on the third conductive layer C3 to transform the third conducive layer C3 into conductive terminals 180. That is, the conductive terminals 180 are formed on the conductive posts 170. In some embodiments, the third conductive layer C3 is reshaped during the reflow process to form hemispherical conductive terminals 180.

Referring to FIG. 1G and FIG. 1H, the structure illustrated in FIG. 1G is singulated to render a plurality of semiconductor dies 100 shown in FIG. 1H. In some embodiments, the singulation process typically involves dicing with a rotation blade and/or a laser beam. In other words, the singulation process includes a laser cutting process, a mechanical cutting process, a laser grooving process, other suitable processes, or a combination thereof. For example, a laser grooving process may be performed on the structure illustrated in FIG. 1G to form trenches (not shown) in the said structure. Thereafter, a mechanical cutting process may be performed on the locations of the trenches to cut through the said structure, so as to divide the semiconductor wafer 110′ into semiconductor substrates 110 and to obtain the semiconductor die 100.

As illustrated in FIG. 1H, the semiconductor die 100 includes the semiconductor substrate 110, the interconnection structure 120, the dielectric layer 130, the conductive pads 140, the passivation layer 150, the post-passivation layer 160, the conductive posts 170, and the conductive terminals 180. In some embodiments, the semiconductor substrate 110 has a front surface FS and a rear surface RS opposite to the front surface FS. The interconnection structure 120 is disposed on the front surface FS of the semiconductor substrate 110. The dielectric layer 130, the conductive pads 140, the passivation layer 150, and the post-passivation layer 160 are sequentially disposed over the interconnection structure 120. The conductive posts 170 are disposed over the post-passivation layer 160 and are electrically connected to the conductive pads 140. The conductive terminals 180 are disposed on the conductive posts 170.

In some embodiments, the semiconductor die 100 is capable of performing logic functions. For example, the semiconductor die 100 may be a Central Process Unit (CPU) die, a Graphic Process Unit (GPU) die, a Field-Programmable Gate Array (FPGA), or the like. In some embodiments, the semiconductor die 100 may be utilized in a package structure. For example, the semiconductor die 100 may be assembled with other components to form a package structure. The manufacturing process of the package structure utilizing the semiconductor die 100 will be described below.

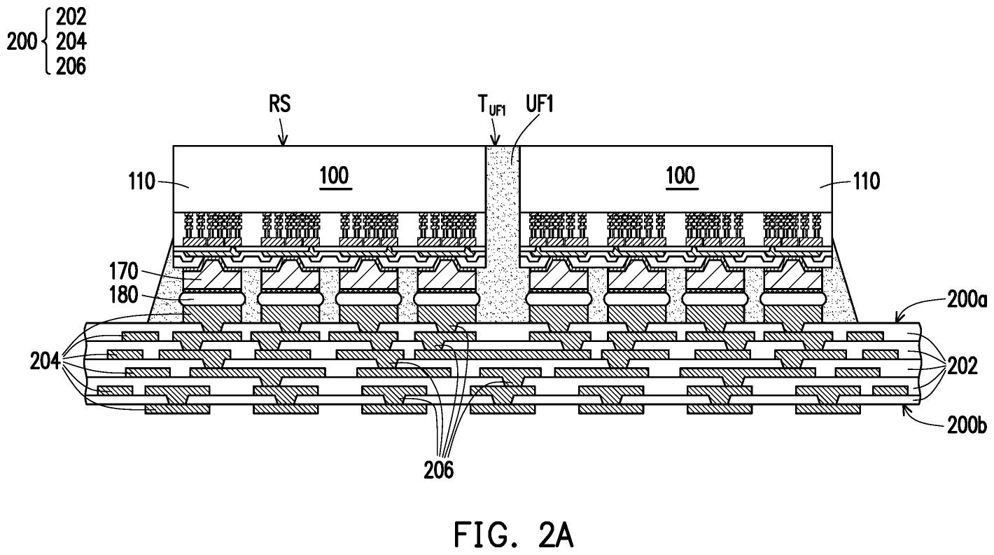

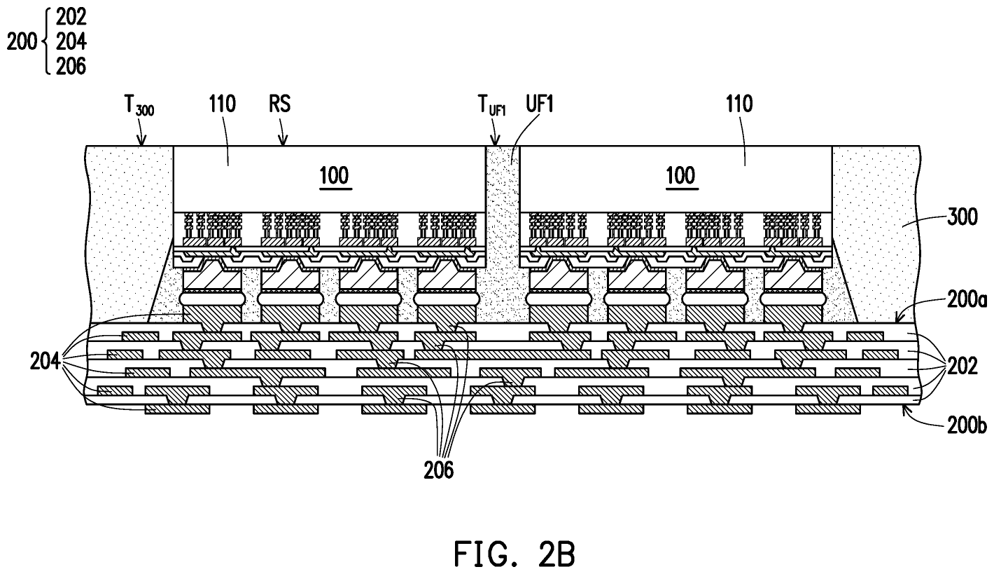

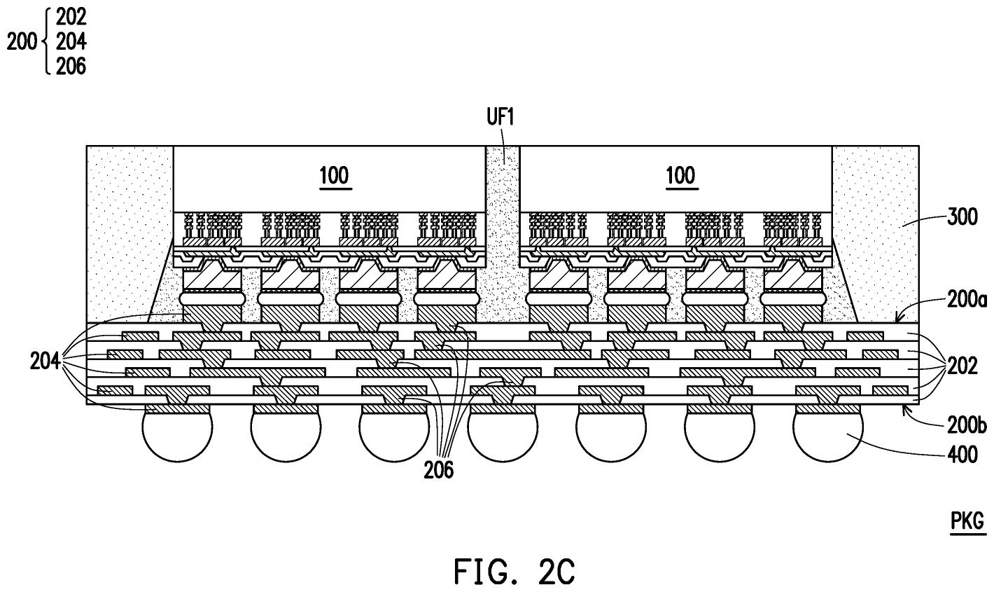

FIG. 2A to FIG. 2C are schematic cross-sectional views illustrating a manufacturing process of a package structure PKG in accordance with some embodiments of the disclosure. Referring to FIG. 2A, an interposer 200 is provided. In some embodiments, the interposer 200 includes a plurality of dielectric layers 202, a plurality of conductive pattern layers 204, and a plurality of conductive vias 206. In some embodiments, the dielectric layers 202 and the conductive pattern layers 204 are stacked alternately. On the other hand, the conductive vias 206 are embedded in the dielectric layers 202. In some embodiments, the conductive pattern layers 204 are interconnected with one another through the conductive vias 206. For example, the conductive vias 206 penetrate through the dielectric layers 202 to connect the conductive pattern layers 204. In some embodiments, each conductive pattern layer 204 includes a plurality of conductive patterns serving as redistribution wirings. In some embodiments, the conductive patterns of the outermost conductive pattern layers 204 (i.e. the topmost conductive pattern layer 204 and the bottommost conductive pattern layer 204) shown in FIG. 2A are referred to as under-ball metallurgy (UBM) patterns for ball mount. In some embodiments, the conductive pattern layers 204 transmit signals horizontally and the conductive vias 206 transmit signals vertically.

In some embodiments, a material of the dielectric layers 202 includes polyimide, epoxy resin, acrylic resin, phenolic resin, benzocyclobutene (BCB), polybenzooxazole (PBO), or any other suitable polymer-based dielectric material. In some embodiments, the dielectric layers 202 include resin mixed with filler. The dielectric layers 202 may be formed by suitable fabrication techniques, such as film lamination, spin-on coating, chemical vapor deposition (CVD), plasma enhanced chemical vapor deposition (PECVD), or the like. In some embodiments, a material of the conductive pattern layers 204 and the conductive vias 206 includes aluminum, titanium, copper, nickel, tungsten, or alloys thereof. The conductive pattern layers 204 and the conductive vias 206 may be formed by electroplating, deposition, and/or photolithography and etching. In some embodiments, the conductive pattern layers 204 and the underlying conductive vias 206 are formed simultaneously. It should be noted that the number of the dielectric layers 202, the number of the conductive pattern layers 204, and the number of the conductive vias 206 illustrated in FIG. 2A are merely for illustrative purposes, and the disclosure is not limited thereto. In some alternative embodiments, fewer or more layers of the dielectric layers 202, the conductive pattern layers 204, and the conductive vias 206 may be formed depending on the circuit design.

In some embodiments, the interposer 200 has a first surface 200a and a second surface 200b opposite to the first surface 200a. The topmost conductive pattern layer 204 is exposed at the first surface 200a and the bottommost conductive pattern layer 204 is exposed at the second surface 200b. As illustrated in FIG. 2A, the interposer 200 is a redistribution layer (RDL) interposer. However, the disclosure is not limited thereto. In some alternative embodiments, other types of interposer, such as silicon interpose, organic interposer, or the like, may be utilized as the interposer 200.

As illustrated in FIG. 2A, a plurality of semiconductor dies 100 in FIG. 1H is bonded to the first surface 200a of the interposer 200. In some embodiments, the semiconductor dies 100 are attached to the interposer 200 through the conductive terminals 180. For example, the conductive terminals 180 of the semiconductor dies 100 are in physical contact with the topmost conductive pattern layer 204 exposed at the first surface 200a of the interposer 200 to render electrical connection between the semiconductor dies 100 and the interposer 200. In some embodiments, after the conductive terminals 180 are attached to the topmost conductive pattern layer 204 of the interposer 200, a reflow process is performed to reshape the conductive terminals 180.

In some embodiments, the semiconductor dies 100 are attached to the interposer 200 through flip-chip bonding. In other words, the semiconductor dies 100 are placed such that the rear surfaces RS of the semiconductor substrates 110 face upward. As shown in FIG. 2A, two semiconductor dies 100 are bonded to the interposer 200. However, it should be noted that the number of the semiconductor dies 100 shown in FIG. 2A is merely an exemplary illustration, and the disclosure is not limited. In some alternative embodiments, the number of the semiconductor dies 100 may be adjusted depending on the design. For example, one single semiconductor die 100 may be bonded to the interposer 200 or more than two semiconductor dies 100 may be bonded to the interposer 200. Furthermore, as shown in FIG. 2A, two identical semiconductor dies 100 are bonded to the interposer 200. However, the disclosure is not limited thereto. In some alternative embodiments, semiconductor dies with different functions may be bonded to the interposer 200. For example, as mentioned above, the semiconductor die 100 is capable of performing logic functions. Therefore, in some alternative embodiments, one of the semiconductor dies 100 may be replaced by another die that is capable of performing storage function. For example, one of the semiconductor dies 100 may be replaced by a Dynamic Random Access Memory (DRAM), a Resistive Random Access Memory (RRAM), a Static Random Access Memory (SRAM), or the like.

In some embodiments, an underfill layer UF1 is formed over the interposer 200 to partially encapsulate the semiconductor dies 100. For example, the underfill layer UF1 wraps around the conductive posts 170 and the conductive terminals 180 of the semiconductor dies 100. The underfill layer UF1 also completely covers an inner sidewall of each semiconductor die 100 and partially covers outer sidewalls of each semiconductor die 100. For example, the portion of the underfill layer UF1 located between two adjacent semiconductor dies 100 has a top surface T_{UF1} that is substantially coplanar with the rear surfaces RS of the semiconductor substrates 110 of the semiconductor dies 100. However, the disclosure is not limited thereto. In some alternative embodiments, the top surface T_{UF1} of the underfill layer UF1 may be located below or above the rear surfaces RS of the semiconductor substrates 110. In some embodiments, a material of the underfill layer UF1 is an insulating material and includes a resin (e.g., epoxy resin), a filler material, a stress release agent (SRA), an adhesion promoter, other material, or a combination thereof. In some embodiments, the underfill layer UF1 is optional.

Referring to FIG. 2B, an encapsulant 300 is formed over the interposer 200 to encapsulate the semiconductor dies 100 and the underfill layer UF1. For example, the encapsulant 300 laterally encapsulates the semiconductor dies 100 and the underfill layer UF1. As illustrated in FIG. 2B, a top surface T₃₀₀ of the encapsulant 300 is substantially coplanar with the rear surfaces RS of the semiconductor substrates 110 of the semiconductor dies 100 and the top surface T_{UF1} of the underfill layer UF1. That is, the encapsulant 300 exposes the semiconductor substrates 110 of the semiconductor dies 100. In some embodiments, the encapsulant 300 is a molding compound, a molding underfill, a resin (such as epoxy), or the like. In some embodiments, the encapsulant 300 includes fillers. The fillers may be particles made of silica, aluminum dioxide, or the like. In some embodiments, the encapsulant 300 is formed by a molding process, an injection process, a combination thereof, or the like. The molding process includes, for example, a transfer molding process, a compression molding process, or the like.

Referring to FIG. 2C, a plurality of conductive terminals 400 is formed on the second surface 200b of the interposer 200. In some embodiments, the conductive terminals 400 are solder balls, ball grid array (BGA) balls, or the like. In some embodiments, the conductive terminals 400 are made of a conductive material with low resistivity, such as Sn, Pb, Ag, Cu, Ni, Bi, or an alloy thereof. In some embodiments, the conductive terminals 400 are in physical contact with the bottommost conductive pattern layer 204 exposed at the second surface 200b of the interposer 200.

After the conductive terminals 400 are formed, a singulation process is performed on the encapsulant and the interposer 200 to obtain a plurality of package structures PKG. In some embodiments, the singulation process typically involves dicing with a rotation blade and/or a laser beam. In other words, the singulation process includes a laser cutting process, a mechanical cutting process, a laser grooving process, other suitable processes, or a combination thereof. In some embodiments, since the interposer 200 is in wafer form, the package structure PKG is considered to be formed by a chip-on-wafer process.

In some embodiments, the package structure PKG may be utilized in a semiconductor device. For example, the package structure PKG may be assembled with other components to form a semiconductor device. The manufacturing process of the semiconductor device utilizing the package structure PKG will be described below.

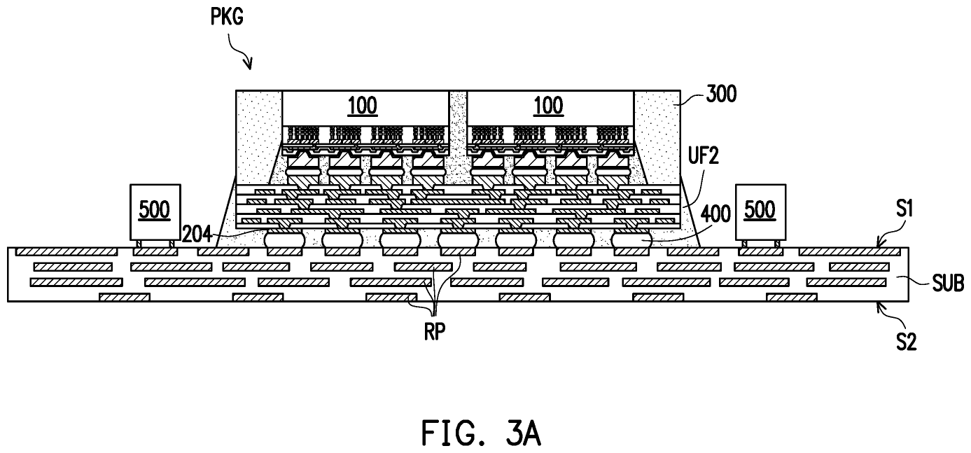

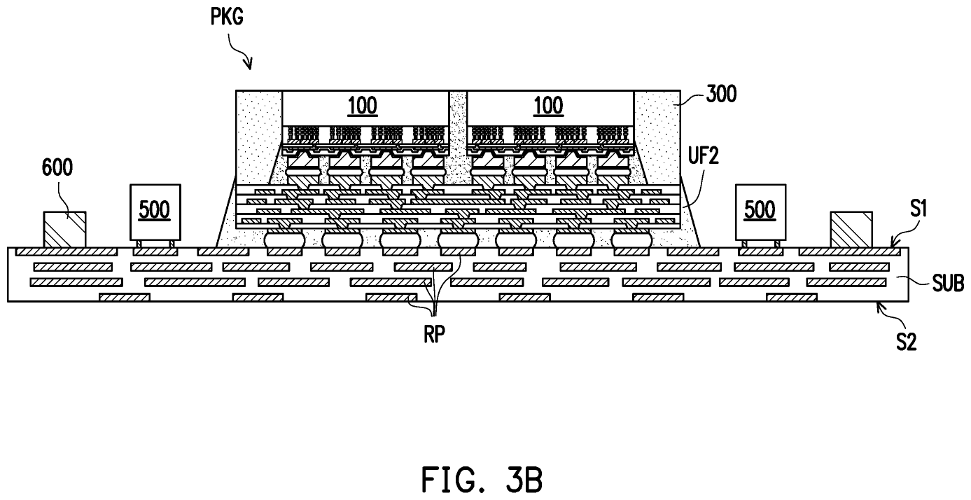

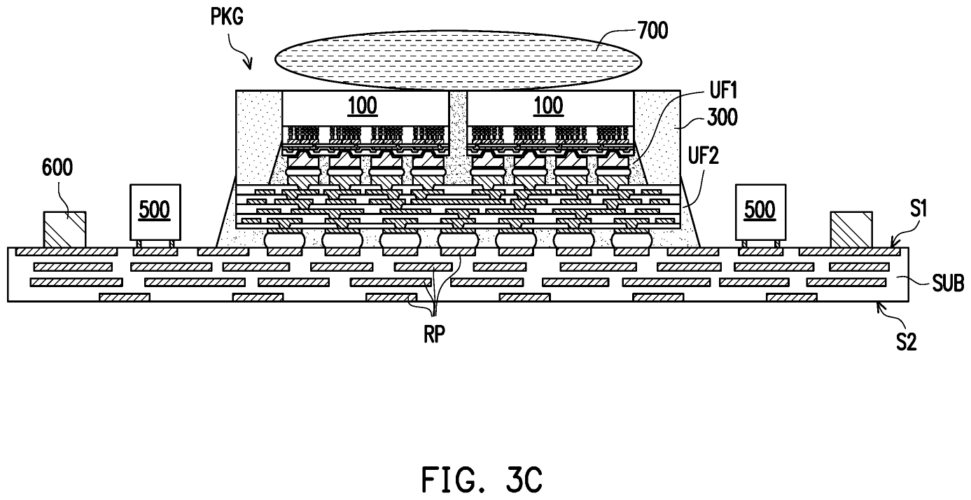

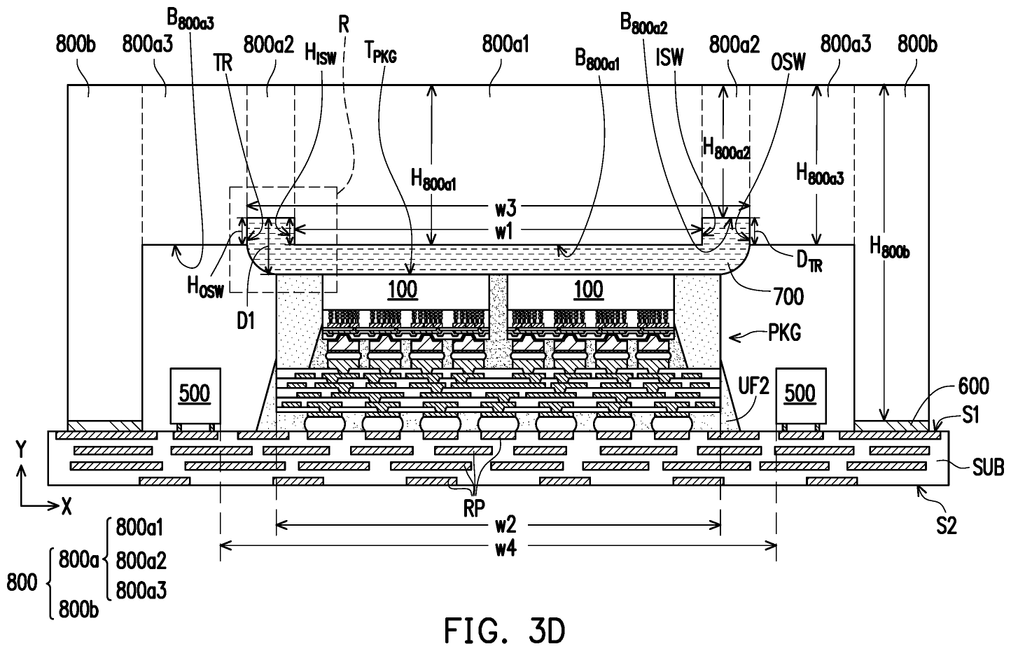

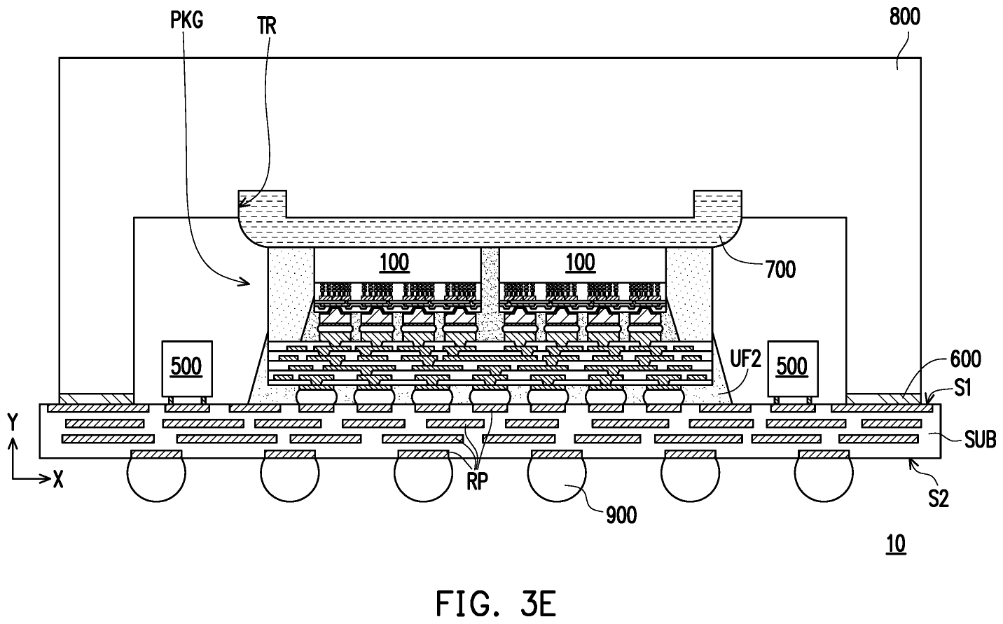

FIG. 3A to FIG. 3E are schematic cross-sectional views illustrating a manufacturing process of a semiconductor device 10 in accordance with some embodiments of the disclosure. Referring to FIG. 3A, a substrate SUB is provided. In some embodiments, the substrate SUB is a printed circuit board (PCB) or the like. In some embodiments, the substrate SUB is referred to as a circuit substrate. In some embodiments, the substrate SUB includes a plurality of routing patterns RP embedded therein. In some embodiments, the routing patterns RP are interconnected with one another. That is, the routing patterns RP are electrically connected to one another. As illustrated in FIG. 3A, the substrate SUB has a first surface S1 and a second surface S2 opposite to the first surface S1. In some embodiments, some of the routing patterns RP are exposed at the first surface S1 and some of the routing patterns RP are exposed at the second surface S2.

As illustrated in FIG. 3A, the package structure PKG in FIG. 2C is bonded to the first surface S1 of the substrate SUB. In some embodiments, the package structure PKG is attached to the substrate SUB through the conductive terminals 400. For example, the conductive terminals 400 of the package structure PKG are in physical contact with the routing patterns RP exposed at the first surface S1 of the substrate SUB to render electrical connection between the package structure PKG and the substrate SUB. In some embodiments, after the conductive terminals 400 are attached to the routing patterns RP of the substrate SUB, a reflow process may be performed to reshape the conductive terminals 400.

In some embodiments, an underfill layer UF2 is formed between the package structure PKG and the first surface S1 of the substrate SUB. For example, the underfill layer UF2 wraps around the bottommost conductive pattern layer 204 and the conductive terminals 400 of the package structure PKG. In some embodiments, the underfill layer UF2 is utilized to protect these elements. In some embodiments, the underfill layer UF2 further covers portions of each sidewall of the package structure PKG. In some embodiments, a material of the underfill layer UF2 is an insulating material and includes a resin (e.g., epoxy resin), a filler material, a stress release agent (SRA), an adhesion promoter, other material, or a combination thereof. In some embodiments, the underfill layer UF2 is optional.

As illustrated in FIG. 3A, a plurality of passive components 500 is also bonded to the first surface S1 of the substrate SUB. In some embodiments, the passive components 500 are mounted on the routing patterns RP of the substrate SUB through a soldering process, a reflowing process, a combination thereof, or other suitable processes. In some embodiments, the passive components 500 include capacitors, resistors, inductors, fuses, or the like. As illustrated in FIG. 3A, the passive components 500 are disposed aside the package structure PKG. For example, the passive components 500 may be disposed to surround the package structure PKG.

Referring to FIG. 3B, an adhesive layer 600 is formed on the first surface S1 of the substrate SUB. For example, the adhesive layer 600 is formed near edges of the first surface S1 of the substrate SUB to surround/encircle the package structure PKG, the underfill layer UF2, and the passive components 500. In some embodiments, the adhesive layer 600 partially covers the first surface S1 of the substrate SUB. For example, the package structure PKG, the underfill layer UF2, and the passive components 500 are physically isolated from the adhesive layer 600. In some embodiments, a shape of the adhesive layer 600 depends on the shape of the substrate SUB. For example, when the substrate SUB is in wafer form (i.e. having a circular top view), the adhesive layer 600 exhibits a circular ring shape from the top view. When the substrate SUB is in panel form (i.e. having a rectangular or squared top view), the adhesive layer exhibits a rectangular ring shape or a squared ring shape from the top view. In some embodiments, the adhesive layer 600 is applied onto the substrate SUB through dispensing, spin-coating, or the like. In some embodiments, the adhesive layer 600 has a thermal conductivity lower than about 0.5 W/m·K. In some embodiments, the adhesive layer 600 includes an epoxy-based material. However, the disclosure is not limited to. In some alternative embodiments, other polymeric materials having adhering property may be utilized as the adhesive layer 600.

Referring to FIG. 3C, a thermal interface material (TIM) layer 700 is formed on the package structure PKG. In some embodiments, a material of the TIM layer 700 is different from the material of the adhesive layer 600. For example, the TIM layer 700 has a lower adhering ability and a higher thermal conductivity than the adhesive layer 600. In some embodiments, the TIM layer 700 includes a liquid state metal material. The liquid state metal material includes gallium, indium, tin, zinc, or a combination thereof. For example, the TIM layer 700 may be made of Galinstan (68% Ga, 21.5% In, and 10.0% Sn by weight), EGaIn (Gallium-Indium eutectic; 75.5% Ga and 24.5% In by weight), or the like. In some embodiments, a thermal conductivity of the TIM layer 700 ranges from about 10 W/m·K to about 100 W/m·K. In some embodiments, the TIM layer 700 is in a liquid state and is applied onto the package structure PKG through a dispensing process. In some embodiments, the TIM layer 700 has a high surface tension ranging from about 0.624 N/m to about 0.718 N/m. For example, when the TIM layer 700 is made of Galinstan, the TIM layer 700 has the surface tension of 0.718 N/m. Meanwhile, when the TIM layer 700 is made of EGaIn, the TIM layer 700 has the surface tension of 0.624 N/m. In some embodiments, due to the high surface tension of the liquid state metal material, the TIM layer 700 may aggregate to form a big droplet after dispensing. For example, as illustrated in FIG. 3C, the TIM layer 700 has a circular or elliptical cross-sectional view. However, the disclosure is not limited thereto. In some alternative embodiments, the TIM layer 700 may have a hemispherical cross-sectional view. As illustrated in FIG. 3C, the TIM layer 700 is in physical contact with the semiconductor dies 100, the underfill layer UF1, and the encapsulant 300. That is, the TIM layer 700 is in physical contact with the package structure PKG.

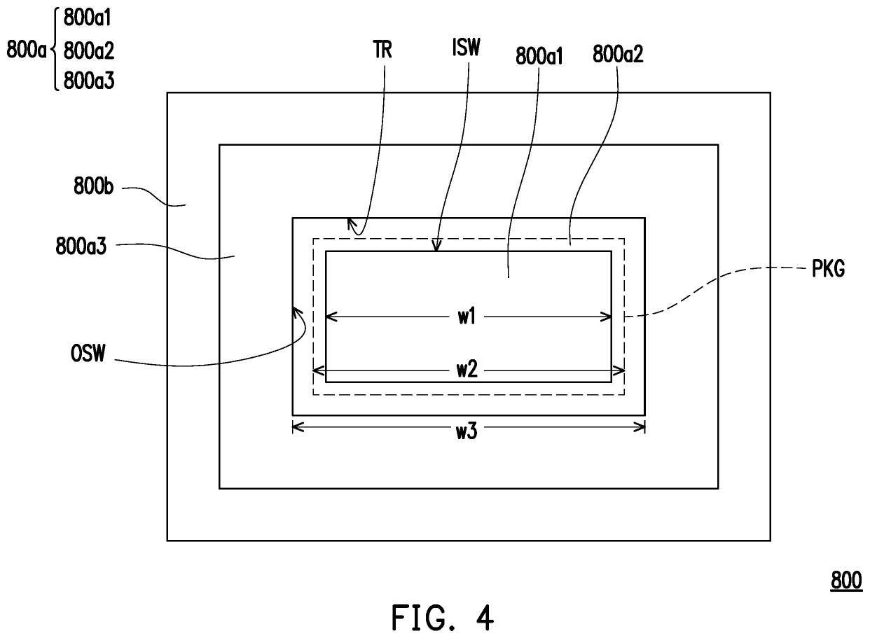

Referring to FIG. 3D, a lid structure 800 is provided. In some embodiment, the lid structure 800 is made of metal, plastic, ceramics, or the like. The metal for the lid structure 800 includes, but is not limited to, copper, stainless steel, solder, gold, nickel, molybdenum, NiFe, NiFeCr, or an alloy thereof. The configuration of the lid structure 800 will be discussed in detail below in conjunction with FIG. 3D and FIG. 4.

FIG. 4 is a schematic bottom view of the lid structure 800 in FIG. 3D. Referring to FIG. 3D and FIG. 4, the lid structure 800 includes a cover portion 800a and a leg portion 800b connected to the cover portion 800a. In some embodiments, an extending direction of the cover portion 800a is different from an extending direction of the leg portion 800b. For example, the cover portion 800a extends along the X-direction while the leg portion 800b extends along the Y-direction. In other words, the extending direction of the cover portion 800a is perpendicular to the extending direction of the leg portion 800b. In some embodiments, the cover portion 800a and the leg portion 800b are integrally formed. As illustrated in FIG. 4, the leg portion 800b exhibits a ring shape from the bottom view.

In some embodiments, the lid structure 800 includes a trench TR on a bottom surface thereof. For example, the cover portion 800a has the trench TR on a bottom surface thereof. As illustrated in FIG. 4, the trench TR exhibits a ring shape from the bottom view. In some embodiments, the trench TR has an inner sidewall ISW and an outer sidewall OSW surrounding the inner sidewall ISW. As illustrated in FIG. 3D, a height H_{ISW} of the inner sidewall ISW of the trench TR is substantially equal to a height H_{OSW} of the outer sidewall OSW of the trench TR. In other words, a depth D_{TR} of the trench TR is uniform. In some embodiments, the height H_{ISW} of the inner sidewall ISW of the trench TR and the height H_{OSW} of the outer sidewall OSW of the trench TR range from about 0.1 mm to about 1 mm. In other words, the depth D_{TR} of the trench TR also ranges from about 0.1 mm to about 1 mm. It should be noted that although FIG. 4 illustrated that the trench TR is a continuous ring from the bottom view, the configuration of the trench TR is not limited thereto. In some alternative embodiments, the trench TR may include a plurality of squared recesses arranged in a ring shape, or the trench TR may include a plurality of discontinuous strip-like recesses arranged in a ring shape.

In some embodiments, the trench TR divides the cover portion 800a into multiple portions. For example, the cover portion 800a may include a first portion 800a1, a second portion 800a2, and a third portion 800a3. The first portion 800a1 is connected to the second portion 800a2, and the second portion 800a2 is connected to the third portion 800a3. In other words, the second portion 800a2 is sandwiched between the first portion 800a1 and the third portion 800a3. In some embodiments, the third portion 800a3 is connected to the leg portion 800b. For example, the third portion 800a3 connects the second portion 800a2 and the leg portion 800b. As illustrated in FIG. 4, the first portion 800a1 exhibits a rectangular shape from the bottom view. Meanwhile, the second portion 800a2 and the third portion 800a3 respectively exhibit a ring shape from the bottom view. As illustrated in FIG. 3D, the trench TR is located between the first portion 800a1 and the third portion 800a3. On the other hand, the second portion 800a2 is located directly above the trench TR. In other words, the trench TR and the second portion 800a2 together separate the first portion 800a1 from the third portion 800a3.

As illustrated in FIG. 3D, a height H₈₀₀ₐ₁ of the first portion 800a1 is different from a height H₈₀₀ₐ₂ of the second portion 800a2. For example, the height H₈₀₀ₐ₁ of the first portion 800a1 is greater than the height H₈₀₀ₐ₂ of the second portion 800a2. Similarly, a height H₈₀₀ₐ₃ of the third portion 800a3 is different form the height H₈₀₀ₐ₂ of the second portion 800a2. For example, the height H₈₀₀ₐ₃ of the third portion 800a3 is greater than the height H₈₀₀ₐ₂ of the second portion 800a2. Meanwhile, the height 1⁻1₈₀₀ₐᵢ of the first portion 800a1 is substantially equal to the height H₈₀₀ₐ₃ of the third portion 800a3. In some embodiments, the height H₈₀₀ₐ₁ of the first portion 800a1 and the height H₈₀₀ₐ₃ of the third portion 800a3 range from about 0.5 mm to about 2 mm. On the other hand, the height H₈₀₀ₐ₂ of the second portion 800a2 ranges from about 0.1 mm to about 1.9 mm. In some embodiments, a height H_{800b} of the leg portion 800b is greater than the height H₈₀₀ₐ₁ of the first portion 800a1, the height H₈₀₀ₐ₂ of the second portion 800a2, and the height H₈₀₀ₐ₃ of the third portion 800a3. In some embodiments, the height H_{800b} of the leg portion 800b ranges from about 1.2 mm to about 3 mm.

As illustrated in FIG. 3D, the lid structure 800 is placed over the substrate SUB, the package structure PKG, and the passive components 500. For example, the lid structure 800 is placed on the adhesive layer 600 and the TIM layer 700 to be in physical contact with these elements. In some embodiments, the lid structure 800 is placed such that the trench TR faces the package structure PKG. Thereafter, the lid structure 800 is being pressed against the adhesive layer 600 and the TIM layer 700 such that at least a portion of the TIM layer 700 flows into the trench TR of the lid structure 800. Subsequently, a curing process is performed on the adhesive layer 600 and the TIM layer 700 such that the lid structure 800 is attached to the substrate SUB and the package structure PKG respectively through the adhesive layer 600 and the TIM layer 700.

In some embodiments, the leg portion 800b of the lid structure 800 is attached to the substrate SUB through the adhesive layer 600. That is, the adhesive layer 600 is in physical contact with the substrate SUB and the leg portion 800b. For example, the adhesive layer 600 is sandwiched between the substrate SUB and the leg portion 800b of the lid structure 800 to adhere the lid structure 800 to the substrate SUB. As illustrated in FIG. 3D, sidewalls of the leg portion 800b are aligned with sidewalls of the adhesive layer 600. However, the disclosure is not limited thereto. In some alternative embodiments, depending on the amount of the adhesive layer 600 applied in the step illustrated in FIG. 3B, the adhesive layer 600 may overflow over the sidewalls of the leg portion 800b or may be deficient to flow to the sidewalls of the leg portion 800b during the attaching process of the lid structure 800. That is, in some alternative embodiments, sidewalls of the leg portion 800b are not aligned with sidewalls of the adhesive layer 600.

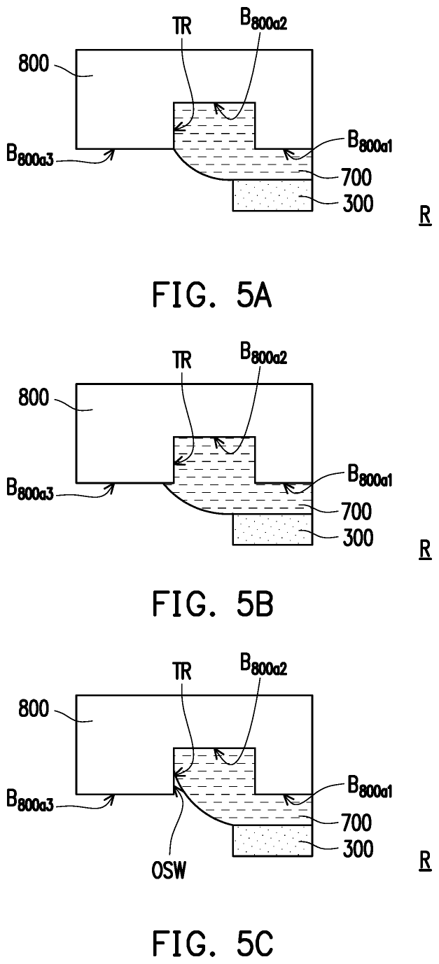

In some embodiments, the cover portion 800a of the lid structure 800 is attached to the package structure PKG through the TIM layer 700. As mentioned above, the lid structure 800 is being pressed against the TIM layer 700. Since the TIM layer 700 is in the liquid state, the TIM layer 700 would flow radially into the trench TR of the lid structure 800 during pressing. In other words, at least a portion of the TIM layer 700 is located in the trench TR of the lid structure 800. Meanwhile, the rest of the TIM layer 700 is located between the package structure PKG and the first portion 800a1 of the cover portion 800a of the lid structure 800, as illustrated in FIG. 3D. In some embodiments, the TIM layer 700 is in physical contact with the package structure PKG and the lid structure 800 to adhere these elements. The geometry of the TIM layer 700 will be discussed below in conjunction with FIG. 3D and FIG. 5A.

FIG. 5A is a schematic enlarged view illustrating a region R in FIG. 3D in accordance with some embodiments of the disclosure. Referring to FIG. 3D and FIG. 5A, the TIM layer 700 completely fills the trench TR and does not overflow. For example, the TIM layer 700 completely covers a bottom surface B₈₀₀ₐ₁ of the first portion 800a1 and a bottom surface B₈₀₀ₐ₂ of the second portion 800a2, but does not cover a bottom surface B₈₀₀ₐ₃ of the third portion 800a3. In other words, the bottom surface B₈₀₀ₐ₃ of the third portion 800a3 is exposed by the TIM layer 700. Due to surface tension, the TIM layer 700 has a curved surface between an edge of the third portion 800a3 and an edge of the encapsulant 300 of the package structure PKG. It should be noted that the configuration of the TIM layer 700 shown in FIG. 5A merely serves as an exemplary illustration, and the disclosure is not limited thereto. Depending on the amount of the TIM layer 700 dispensed in the step illustrated in FIG. 3C, the TIM layer 700 in FIG. 3D may exhibit other geometries in some alternative embodiments. Other geometries of the TIM layer 700 will be discussed below in conjunction with FIG. 5B and FIG. 5C.

FIG. 5B is a schematic enlarged view illustrating a region R in FIG. 3D in accordance with some alternative embodiments of the disclosure. Referring to FIG. 5B, when the amount of the TIM layer 700 dispensed is excessive, the trench TR is not big enough to accommodate the TIM layer 700 flow into the trench. Therefore, the TIM layer 700 would overflow to partially cover the bottom surface B₈₀₀ₐ₃ of the third portion 800a3. That is, the TIM layer 700 completely covers the bottom surface B₈₀₀ₐ₁ of the first portion 800a1 and the bottom surface B₈₀₀ₐ₂ of the second portion 800a2, but partially covers the bottom surface B₈₀₀ₐ₃ of the third portion 800a3. It should be noted that the term “excessive” herein refers to a scenario where the amount of the TIM layer 700 dispensed is more than that of in FIG. 5A. Due to surface tension, the TIM layer 700 has a curved surface between the bottom surface B₈₀₀ₐ₃ of the third portion 800a3 and an edge of the encapsulant 300 of the package structure PKG.

FIG. 5C is a schematic enlarged view illustrating a region R in FIG. 3D in accordance with some alternative embodiments of the disclosure. Referring to FIG. 5C, when the amount of the TIM layer 700 dispensed is deficient, the TIM layer 700 cannot fill up the entire trench TR. For example, as illustrated in FIG. 5C, a portion of the outer sidewall OSW of the trench TR is exposed by the TIM layer 700. In some embodiments, the TIM layer 700 completely covers a bottom surface B₈₀₀ₐ₁ of the first portion 800a1 and a bottom surface B₈₀₀ₐ₂ of the second portion 800a2, but does not cover a bottom surface B₈₀₀ₐ₃ of the third portion 800a3. In other words, the bottom surface B₈₀₀ₐ₃ of the third portion 800a3 is exposed by the TIM layer 700. It should be noted that the term “deficient” herein refers to a scenario where the amount of the TIM layer 700 dispensed is less than that of in FIG. 5A while still being sufficient enough to securely adhere the lid structure 800 to the package structure PKG. Due to surface tension, the TIM layer 700 has a curved surface between the outer sidewall OSW of the trench TR and an edge of the encapsulant 300 of the package structure PKG.

Referring back to FIG. 3D and FIG. 4, a width w1 of the first portion 800a1 is smaller than a width w2 of the package structure PKG. In other words, a vertical projection of the first portion 800a1 onto the substrate SUB is located within a span of a vertical projection of the package structure PKG onto the substrate SUB. In some embodiments, the width w1 of the first potion 800a1 ranges from about 0.4 mm to about 99.9 mm, and the width w2 of the package structure PKG ranges from about 0.5 mm to about 100 mm. In some embodiments, a total width w3 of the first portion 800a1 and the second portion 800a2 is greater than the width w2 of the package structure PKG. For example, the total width w3 of the first portion 800a1 and the second portion 800a2 ranges from about 0.55 mm to about 105 mm. In some embodiments, the trench TR is configured such that (w3-w2)/2 ranges from about 0.5 m to about 5 mm. As illustrated in FIG. 3D and FIG. 4, a contour of a vertical projection of the package structure PKG onto the lid structure 800 is located within the trench TR. That is, a vertical projection of the trench TR onto the substrate SUB is partially overlapped with the vertical projection of the package structure PKG onto the substrate SUB. In some embodiments, a width w4 between two passive components 500 is greater than the total width w3 of the first portion 800a1 and the second portion 800a2. In other words, the passive components 500 are located directly underneath the third portion 800a3. In some embodiments, the width w4 between two passive component 500 ranges from about 2.5 mm to about 102 mm. As illustrated in FIG. 3D, a top surface T_{PKG} of the package structure PKG is located at a level height lower than that of the bottom surface B₈₀₀ₐ₁ of the first portion 800a1, the bottom surface B₈₀₀ₐ₂ of the second portion 800a2, and the bottom surface B₈₀₀ₐ₃ of the third portion 800a3. In some embodiments, a distance D1 between the bottom surface B₈₀₀ₐ₂ of the second portion 800a2 and the top surface T_{PKG} of the package structure PKG ranges from about 0.13 mm to about 1.1 mm.

As illustrated in FIG. 3D, the lid structure 800 and the substrate SUB together encloses the package structure PKG and the passive components 500. In other words, the package structure PKG and the passive components 500 are disposed between the substrate SUB and the cover portion 800a of the lid structure 800. In some embodiments, the leg portion 800b of the lid structure 800 is spatially separated from the package structure PKG, the underfill layer UF2, and the passive components 500. In some embodiments, the cover portion 800a of the lid structure 800 is disposed over the package structure PKG and is spatially separated from the substrate SUB.

In some embodiments, with the adoption of the liquid state metal material as the TIM layer 700, the conventional backside metal (BSM) process and the conventional jetting process, which are being utilized to promote adhesion between the TIM layer and the lid structure and/or between the TIM layer and the package structure, may be omitted. In other words, the TIM layer 700 is directly in contact with both of the package structure PKG and the lid structure 800, and no solder interface is seen between these elements. In some embodiments, the solder interface would cause high stress during thermal processes. However, since no solder interface is presented between the package structure PKG, the TIM layer 700, and the lid structure 800, the issue of high stress may be sufficiently eliminated. In addition, as mentioned above, a curing process is performed on the adhesive layer 600 and the TIM layer 700 to securely fix the lid structure 800 onto the substrate SUB and the package structure PKG. In some embodiments, after the curing process, the TIM layer 700 remains in the liquid state. That is, the liquid state metal material of the TIM layer 700 is in the liquid state before and after curing. In some embodiments, although still in liquid form, due to the high surface tension of the TIM layer 700, the surface tension is able to hold the TIM layer 700 in place (i.e. securely attached to the lid structure 800) without dropping down to contaminate other components most of the time. However, there are still occasions that the surface tension is not strong enough to resist the gravitational force, and the TIM layer 700 would drip down to contaminate other components. In some embodiments, with the presence of the trench TR in the lid structure 800, the TIM layer 700 is further fixed within the trench TR due to surface tension, thereby further ensuring the fastness of the TIM layer 700.

Referring to FIG. 3E, a plurality of conductive terminals 900 is formed on the second surface S2 of the substrate SUB to obtain the semiconductor device 10. In some embodiments, the conductive terminals 900 are solder balls, ball grid array (BGA) balls, or the like. In some embodiments, the conductive terminals 900 are made of a conductive material with low resistivity, such as Sn, Pb, Ag, Cu, Ni, Bi, or an alloy thereof. In some embodiments, the conductive terminals 900 are in physical contact with the routing patterns RP exposed at the second surface S2 of the substrate SUB.

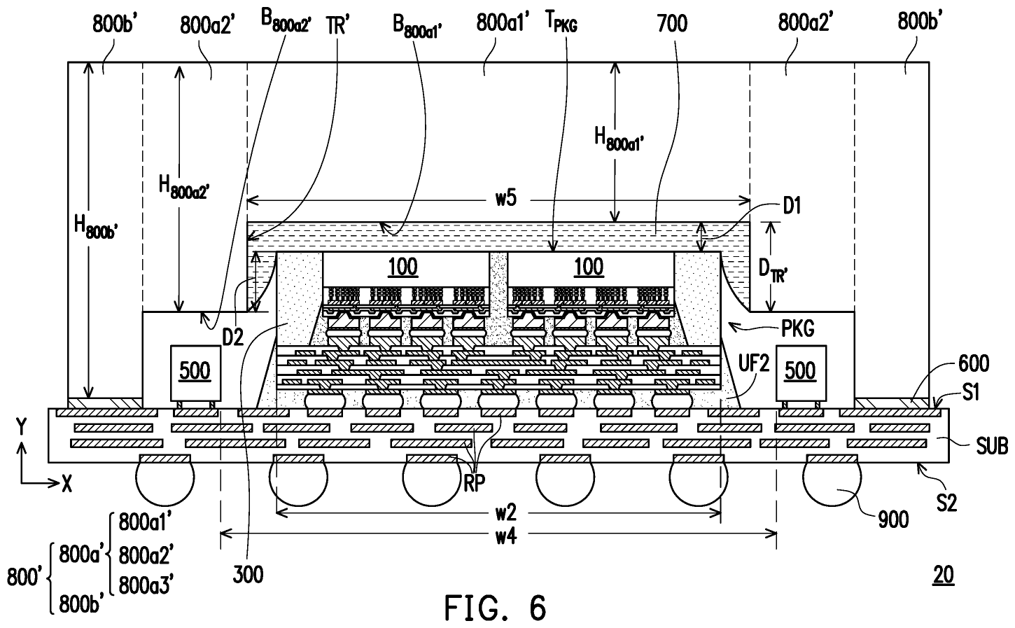

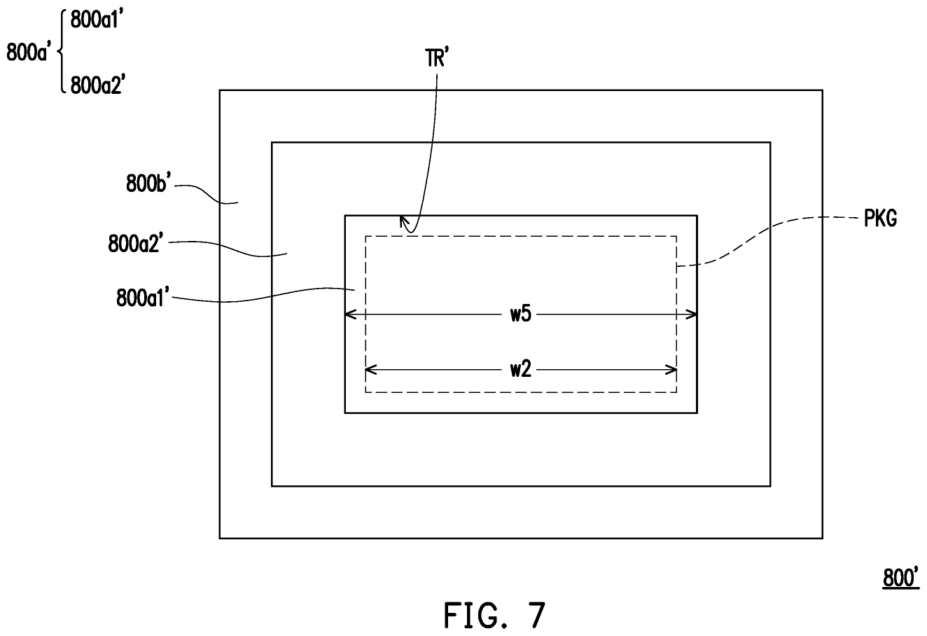

FIG. 6 is a schematic cross-sectional view illustrating a semiconductor device 20 in accordance with some alternative embodiments of the disclosure. FIG. 7 is a schematic bottom view of the lid structure 800′ in FIG. 6. Referring to FIG. 6 and FIG. 7, the semiconductor device 20 in FIG. 6 is similar to the semiconductor device 10 in FIG. 3E, so similar elements are denoted by the same reference numeral, and the detailed descriptions thereof are omitted herein. However, the lid structure 800 in FIG. 3E is replaced by the lid structure 800′ in FIG. 6 and FIG. 7. In some embodiments, a material of the lid structure 800′ in FIG. 6 and FIG. 7 is similar to that of the lid structure 800 in FIG. 3E, so the detailed description thereof is omitted herein.

In some embodiments, the lid structure 800′ includes a cover portion 800a′ and a leg portion 800b′ connected to the cover portion 800a′. In some embodiments, an extending direction of the cover portion 800a′ is different from an extending direction of the leg portion 800b′. For example, the cover portion 800a′ extends along the X-direction while the leg portion 800b′ extends along the Y-direction. In other words, the extending direction of the cover portion 800a′ is perpendicular to the extending direction of the leg portion 800b′. In some embodiments, the cover portion 800a′ and the leg portion 800b′ are integrally formed. As illustrated in FIG. 7, the leg portion 800b′ exhibits a ring shape from the bottom view.

In some embodiments, the lid structure 800′ includes a trench TR′ on a bottom surface thereof. For example, the cover portion 800a′ has the trench TR′ on a bottom surface thereof. As illustrated in FIG. 7, the trench TR′ exhibits a rectangular shape from the bottom view. In some embodiments, a depth D_{TR}′ of the trench TR′ is uniform. For example, the depth D_{TR}′ of the trench TR′ ranges from about 0.5 mm to about 1 mm.

In some embodiments, the cover portion 800a′ includes a first portion 800a1′ and a second portion 800a2′ connected to the first portion 800a1′. In some embodiments, the second portion 800a2′ is connected to the leg portion 800b′. For example, the second portion 800a2′ connects the first portion 800a1′ and the leg portion 800b′. As illustrated in FIG. 7, the first portion 800a1′ exhibits a rectangular shape from the bottom view. Meanwhile, the second portion 800a2′ exhibits a ring shape from the bottom view. As illustrated in FIG. 6, the second portion 800a2′ encloses the trench TR′. On the other hand, the first portion 800a1′ is located directly above the trench TR′.

As illustrated in FIG. 6, a height H₈₀₀ₐ₁ of the first portion 800a1′ is different from a height H₈₀₀ₐ₂′ of the second portion 800a2′. For example, the height H₈₀₀ₐ₁ of the first portion 800a1′ is smaller than the height H₈₀₀ₐ₂′ of the second portion 800a2′. In some embodiments, the height H_{800a1′} of the first portion 800a1′ ranges from about 0.5 mm to about 2 mm. On the other hand, the height H_{800a2′}′ of the second portion 800a2′ ranges from about 0.6 mm to about 2.3 mm. In some embodiments, a height H_{800b′} of the leg portion 800b′ is greater than the height H_{800a1′} of the first portion 800a1′ and the height H_{800a2′} of the second portion 800a2′. In some embodiments, the height H_{800b′} of the leg portion 800b′ ranges from about 1.2 mm to about 3 mm.

As illustrated in FIG. 6, the TIM layer 700 is located within the trench TR′ and does not overflow to outside of the trench TR′. For example, the TIM layer 700 completely covers a bottom surface B_{800a1′} of the first portion 800a1′, but does not cover a bottom surface B₈₀₀ₐ₂, of the second portion 800a2′. In other words, the bottom surface B₈₀₀ₐ₂′ of the second portion 800a2′ is exposed by the TIM layer 700. Due to surface tension, the TIM layer 700 has a curved surface between an edge of the second portion 800a2′ and an edge of the encapsulant 300 of the package structure PKG. It should be noted that the configuration of the TIM layer 700 shown in FIG. 6 merely serves as an exemplary illustration, and the disclosure is not limited thereto. Depending on the amount of the TIM layer 700 dispensed, other geometries (such as the geometries illustrated in FIG. 5B and FIG. 5C) are also applicable to the semiconductor device 20 in FIG. 6.

In some embodiments, a width w5 of the first portion 800a1′ (i.e. the width of the trench TR′) is larger than a width w2 of the package structure PKG. For example, as illustrated in FIG. 6 and FIG. 7, a vertical projection of the package structure PKG onto the lid structure 800′ is located within the trench TR′. That is, a vertical projection of the trench TR′ onto the substrate SUB is completely overlapped with the vertical projection of the package structure PKG onto the substrate SUB. In some embodiments, the width w5 of the first potion 800a1′ ranges from about 0.55 mm to about 105 mm, and the width w2 of the package structure PKG ranges from about 0.5 mm to about 100 mm. In some embodiments, the trench TR′ is configured such that (w5-w2)/2 ranges from about 0.5 m to about 5 mm. In some embodiments, a width w4 between two passive components 500 is greater than the width w5 of the first portion 800a1′. In other words, the passive components 500 are located directly underneath the second portion 800a2′. In some embodiments, the width w4 between two passive component 500 ranges from about 2.5 mm to about 102 mm. As illustrated in FIG. 3D, a top surface T_{PKG} of the package structure PKG is located at a level height lower than that of the bottom surface B_{800a1′} of the first portion 800a1′. However, the top surface T_{PKG} of the package structure PKG is located at a level height higher than that of the bottom surface B_{800a2′}, of the second portion 800a2′. In other words, the package structure PKG is partially located within the trench TR′ of the lid structure 800′. In some embodiments, a distance D1 between the bottom surface B_{800a1′} of the first portion 800a1′ and the top surface T_{PKG} of the package structure PKG ranges from about 0.03 mm to about 0.1 mm. Moreover, a distance D2 between the bottom surface B_{800a2′} of the second portion 800a2′ and the top surface T_{PKG} of the package structure PKG ranges from about 0.1 mm to about 1 mm.

In some embodiments, a curing process is performed on the adhesive layer 600 and the TIM layer 700 to securely fix the lid structure 800′ onto the substrate SUB and the package structure PKG. In some embodiments, after the curing process, the TIM layer 700 remains in the liquid state. That is, the liquid state metal material of the TIM layer 700 is in the liquid state before and after curing. In some embodiments, although still in liquid form, due to the high surface tension of the TIM layer 700, the surface tension is able to hold the TIM layer 700 in place (i.e. securely attached to the lid structure 800′) without dropping down to contaminate other components most of the time. However, there are still occasions that the surface tension is not strong enough to resist the gravitational force, and the TIM layer 700 would drip down to contaminate other components. In some embodiments, with the presence of the trench TR′ in the lid structure 800′, the TIM layer 700 is further fixed within the trench TR′ due to surface tension, thereby further ensuring the fastness of the TIM layer 700.

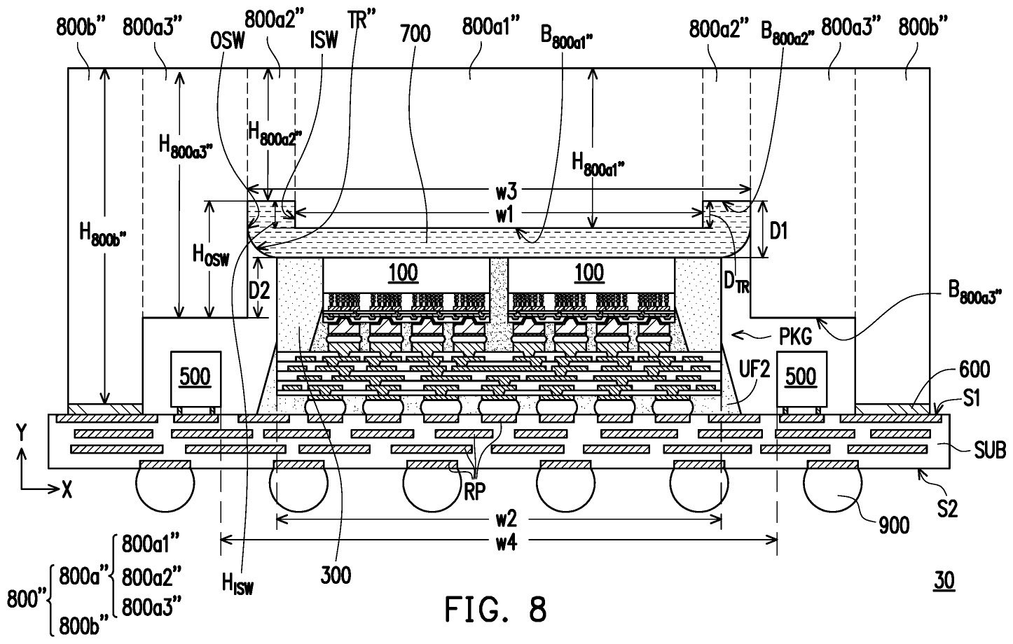

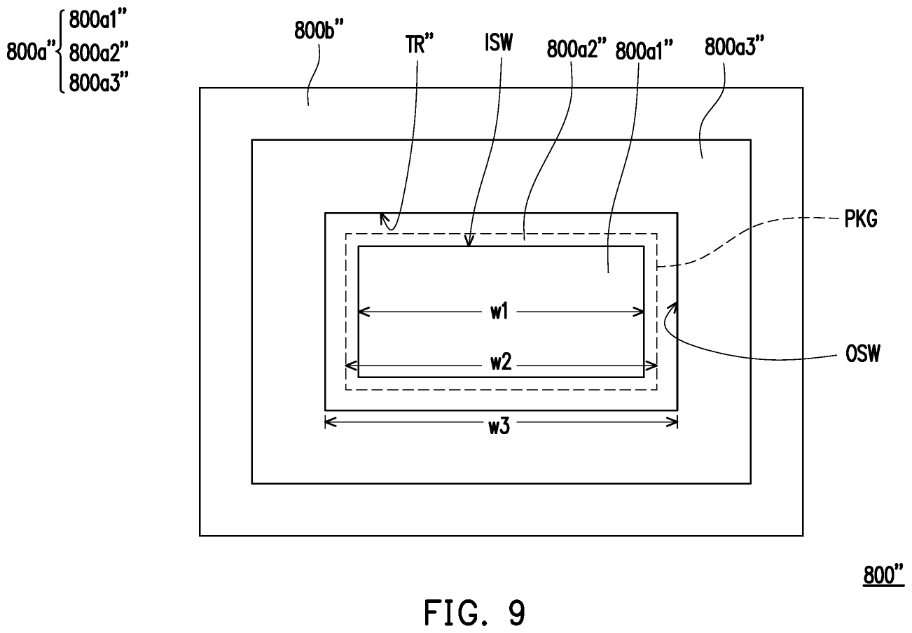

FIG. 8 is a schematic cross-sectional view illustrating a semiconductor device 30 in accordance with some alternative embodiments of the disclosure. FIG. 9 is a schematic bottom view of the lid structure 800″ in FIG. 8. Referring to FIG. 8 and FIG. 9, the semiconductor device 30 in FIG. 8 is similar to the semiconductor device 10 in FIG. 3E, so similar elements are denoted by the same reference numeral, and the detailed descriptions thereof are omitted herein. However, the lid structure 800 in FIG. 3E is replaced by the lid structure 800″ in FIG. 8 and FIG. 9. In some embodiments, a material of the lid structure 800″ in FIG. 8 and FIG. 9 is similar to that of the lid structure 800 in FIG. 3E, so the detailed description thereof is omitted herein. In some embodiments, the lid structure 800″ includes a cover portion 800a″ and a leg portion 800b″ connected to the cover portion 800a″. In some embodiments, an extending direction of the cover portion 800a″ is different from an extending direction of the leg portion 800b″. For example, the cover portion 800a″ extends along the X-direction while the leg portion 800b″ extends along the Y-direction. In other words, the extending direction of the cover portion 800a″ is perpendicular to the extending direction of the leg portion 800b″. In some embodiments, the cover portion 800a″ and the leg portion 800b″ are integrally formed. As illustrated in FIG. 9, the leg portion 800b″ exhibits a ring shape from the bottom view.

In some embodiments, the lid structure 800″ includes a trench TR″ on a bottom surface thereof. For example, the cover portion 800a″ has the trench TR″ on a bottom surface thereof. As illustrated in FIG. 9, the trench TR″ exhibits a ring shape from the bottom view. In some embodiments, the trench TR″ has an inner sidewall ISW and an outer sidewall OSW surrounding the inner sidewall ISW. As illustrated in FIG. 8, a height H_{OSW} of the outer sidewall OSW of the trench TR″ is greater than a height H_{ISW}, of the outer sidewall ISW of the trench TR″. In some embodiments, the height H_{ISW}, of the inner sidewall ISW of the trench TR″ ranges from about 0.1 mm to about 1 mm. On the other hand, the height H_{OSW} of the outer sidewall OSW of the trench TR″ ranges from about 0.05 mm to about 0.3 mm. In some embodiments, a depth D_{TR}-of the trench TR″ ranges from about 0.1 mm to about 1 mm. It should be noted that although FIG. 9 illustrated that the trench TR″ is a continuous ring from the bottom view, the configuration of the trench TR″ is not limited thereto. In some alternative embodiments, the trench TR″ may include a plurality of squared recesses arranged in a ring shape, or the trench TR″ may include a plurality of discontinuous strip-like recesses arranged in a ring shape.

In some embodiments, the trench TR″ divides the cover portion 800a″ into multiple portions. For example, the cover portion 800a″ may include a first portion 800a1″, a second portion 800a2″, and a third portion 800a3″. The first portion 800a1″ is connected to the second portion 800a2″, and the second portion 800a2″ is connected to the third portion 800a3″. In other words, the second portion 800a2″ is sandwiched between the first portion 800a1″ and the third portion 800a3″. In some embodiments, the third portion 800a3″ is connected to the leg portion 800b″. For example, the third portion 800a3″ connects the second portion 800a2″ and the leg portion 800b″. As illustrated in FIG. 9, the first portion 800a1″ exhibits a rectangular shape from the bottom view. Meanwhile, the second portion 800a2″ and the third portion 800a3″ respectively exhibit a ring shape from the bottom view. As illustrated in FIG. 8, the trench TR″ is located between the first portion 800a1″ and the third portion 800a3″. On the other hand, the second portion 800a2″ is located directly above the trench TR″. In other words, the trench TR″ and the second portion 800a2″ together separate the first portion 800a1″ from the third portion 800a3″.

As illustrated in FIG. 8, a height H_{800a1″} of the first portion 800a1″ is different from a height H_{800a2″} of the second portion 800a2″. For example, the height H_{800a1″} of the first portion 800a1″ is greater than the height H_{800a2″} of the second portion 800a2″. Similarly, a height H_{800a3″} of the third portion 800a3″ is different form the height H_{800a2″} of the second portion 800a2″. For example, the height H_{800a3″} of the third portion 800a3″ is greater than the height H_{800a2″} of the second portion 800a2″. Meanwhile, the height H_{800a3″} of the third portion 800a3″ is greater than the height H_{800a1″} of the first portion 800a1″. In some embodiments, the height H_{800a1″} of the first portion 800a1″ ranges from about 0.5 mm to about 2 mm, the height H_{800a2″} of the second portion 800a2″ ranges from about 0.1 mm to about 1.9 mm, and the height H_{800a3″} of the third portion 800a3″ ranges from about 0.6 mm to about 2.3 mm. In some embodiments, a height H_{800b″} of the leg portion 800b″ is greater than the height H_{800a1″} of the first portion 800a1″, the height H_{800a2″} of the second portion 800a2″, and the height H_{800a3″} of the third portion 800a3″. In some embodiments, the height H_{800b″} of the leg portion 800b″ ranges from about 1.2 mm to about 3 mm.

As illustrated in FIG. 8, at least a portion of the TIM layer 700 is located in the trench TR″ of the lid structure 800″. Meanwhile, the rest of the TIM layer 700 is located between the package structure PKG and the first portion 800a1″ of the cover portion 800a″ of the lid structure 800″. In some embodiments, the TIM layer 700 completely fills the trench TR″ and does not overflow. For example, the TIM layer 700 completely covers a bottom surface B_{800a1″} of the first portion 800a1″ and a bottom surface B_{800a2″} of the second portion 800a2″, but does not cover a bottom surface B_{800a3″} of the third portion 800a3″. In other words, the bottom surface B_{800a3″} of the third portion 800a3″ is exposed by the TIM layer 700. Due to surface tension, the TIM layer 700 has a curved surface between an edge of the third portion 800a3″ and an edge of the encapsulant 300 of the package structure PKG. It should be noted that the configuration of the TIM layer 700 shown in FIG. 8 merely serves as an exemplary illustration, and the disclosure is not limited thereto. Depending on the amount of the TIM layer 700 dispensed, other geometries (such as the geometries illustrated in FIG. 5B and FIG. 5C) are also applicable to the semiconductor device 30 in FIG. 8.

In some embodiments, a width w1 of the first portion 800a1″ is smaller than a width w2 of the package structure PKG. In other words, a vertical projection of the first portion 800a1″ onto the substrate SUB is located within a span of a vertical projection of the package structure PKG onto the substrate SUB. In some embodiments, the width w1 of the first potion 800a1″ ranges from about 0.4 mm to about 99.9 mm, and the width w2 of the package structure PKG ranges from about 0.5 mm to about 100 mm. In some embodiments, a total width w3 of the first portion 800a1″ and the second portion 800a2″ is greater than the width w2 of the package structure PKG. For example, the total width w3 of the first portion 800a1″ and the second portion 800a2″ ranges from about 0.55 mm to about 105 mm. In some embodiments, the trench TR″ is configured such that (w3-w2)/2 ranges from about 0.5 m to about 5 mm. As illustrated in FIG. 8 and FIG. 9, a contour of a vertical projection of the package structure PKG onto the lid structure 800 is located within the trench TR″. That is, a vertical projection of the trench TR″ onto the substrate SUB is partially overlapped with the vertical projection of the package structure PKG onto the substrate SUB. In some embodiments, a width w4 between two passive components 500 is greater than the total width w3 of the first portion 800a1″ and the second portion 800a2″. In other words, the passive components 500 are located directly underneath the third portion 800a3″. In some embodiments, the width w4 between two passive component 500 ranges from about 2.05 mm to about 102 mm. As illustrated in FIG. 8, a top surface T_{PKG} of the package structure PKG is located at a level height lower than that of the bottom surface B_{800a1″} of the first portion 800a1″ and the bottom surface B_{800a2″} of the second portion 800a2″. However, the top surface T_{PKG} of the package structure PKG is located at a level height higher than that of the bottom surface B_{800a3″} of the third portion 800a3″. In some embodiments, a distance D1 between the bottom surface B_{800a2″} of the second portion 800a2″ and the top surface T_{PKG} of the package structure PKG ranges from about 0.13 mm to about 1.1 mm. Moreover, a distance D2 between the bottom surface B_{800a3″} of the third portion 800a3″ and the top surface T_{PKG} of the package structure PKG ranges from about 0.1 mm to about 1 mm.

In some embodiments, a curing process is performed on the adhesive layer 600 and the TIM layer 700 to securely fix the lid structure 800″ onto the substrate SUB and the package structure PKG. In some embodiments, after the curing process, the TIM layer 700 remains in the liquid state. That is, the liquid state metal material of the TIM layer 700 is in the liquid state before and after curing. In some embodiments, although still in liquid form, due to the high surface tension of the TIM layer 700, the surface tension is able to hold the TIM layer 700 in place (i.e. securely attached to the lid structure 800″) without dropping down to contaminate other components most of the time. However, there are still occasions that the surface tension is not strong enough to resist the gravitational force, and the TIM layer 700 would drip down to contaminate other components. In some embodiments, with the presence of the trench TR″ in the lid structure 800″, the TIM layer 700 is further fixed within the trench TR″ due to surface tension, thereby further ensuring the fastness of the TIM layer 700.

In accordance with some embodiments of the disclosure, a semiconductor device includes a substrate, a package structure, a thermal interface material (TIM) layer, and a lid structure. The package structure is disposed on the substrate. The TIM layer is disposed on the package structure. The TIM layer includes a liquid state metal material. The lid structure is disposed on the substrate and the TIM layer. The lid structure includes a trench facing the package structure. At least a portion of the TIM layer is located in the trench.

In accordance with some alternative embodiments of the disclosure, a semiconductor device includes a substrate, a lid structure, a package structure, and a thermal interface material (TIM) layer. The lid structure is disposed on the substrate. The lid structure includes a cover portion and a leg portion connected to the cover portion. An extending direction of the cover portion is perpendicular to an extending direction of the leg portion. The cover portion includes a first portion and a second portion connected to the first portion. A height of the first portion is different from a height of the second portion. The package structure is disposed between the substrate and the cover portion of the lid structure. The TIM layer is located between the package structure and the first portion.

In accordance with some embodiments of the disclosure, a manufacturing method of a semiconductor device includes at least the following steps. A substrate is provided. A package structure is bonded to the substrate. An adhesive layer is formed on the substrate. A thermal interface material (TIM) layer is formed on the package structure. The TIM layer includes a liquid state metal material. A lid structure is placed on the adhesive layer and the TIM layer. The lid structure includes a trench on a bottom surface thereof. The lid structure is attached to the substrate and the package structure through the adhesive layer and the TIM layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a package structure disposed on the substrate;
a thermal interface material (TIM) layer disposed on the package structure, wherein the TIM layer comprises a liquid state metal material; and
a lid structure disposed on the substrate and the TIM layer, wherein the lid structure comprises a trench facing the package structure, and at least a portion of the TIM layer is located in the trench.

2. The semiconductor device of claim 1, wherein a vertical projection of the trench onto the substrate is partially overlapped with a vertical projection of the package structure onto the substrate.

3. The semiconductor device of claim 1, wherein a vertical projection of the trench onto the substrate is completely overlapped with a vertical projection of the package structure onto the substrate.

4. The semiconductor device of claim 1, wherein the trench exhibits a ring shape from a bottom view.

5. The semiconductor device of claim 1, wherein the trench comprises an inner sidewall and an outer sidewall surrounding the inner sidewall, and a height of the outer sidewall is substantially equal to a height of the inner sidewall.

6. The semiconductor device of claim 1, wherein the trench comprises an inner sidewall and an outer sidewall surrounding the inner sidewall, and a height of the outer sidewall is greater than a height of the inner sidewall.

7. The semiconductor device of claim 1, wherein the liquid state metal material comprises gallium, indium, tin, zinc, or a combination thereof.

8. A semiconductor device, comprising:
a substrate;
a lid structure disposed on the substrate, wherein the lid structure comprises a cover portion and a leg portion connected to the cover portion, an extending direction of the cover portion is perpendicular to an extending direction of the leg portion, the cover portion comprise a first portion and a second portion connected to the first portion, and a height of the first portion is different from a height of the second portion;
a package structure disposed between the substrate and the cover portion of the lid structure; and
a thermal interface material (TIM) layer located between the package structure and the first portion.

9. The semiconductor device of claim 8, wherein the second portion connects the first portion and the leg portion.

10. The semiconductor device of claim 9, wherein the TIM layer completely covers a bottom surface of the first portion.

11. The semiconductor device of claim 8, wherein the cover portion of the lid structure further comprises a third portion, and the third portion connects the second portion and the leg portion.

12. The semiconductor device of claim 11, wherein a height of the third portion is substantially equal to the height of the first portion.

13. The semiconductor device of claim 11, wherein a height of the third portion is greater than the height of the first portion.

14. The semiconductor device of claim 11, wherein the TIM layer completely covers a bottom surface of the first portion and a bottom surface of the second portion.

15. The semiconductor device of claim 14, wherein the TIM layer further partially covers a bottom surface of the third portion.

16. The semiconductor device of claim 8, wherein a top surface of the package structure is located at a level height lower than that of a bottom surface of the first portion and a bottom surface of the second portion.

17. The semiconductor device of claim 8, wherein a top surface of the package structure is located at a level height higher than that of a bottom surface of the second portion.

18. A manufacturing method of a semiconductor device, comprising:
providing a substrate;
bonding a package structure to the substrate;
forming an adhesive layer on the substrate;
forming a thermal interface material (TIM) layer on the package structure, wherein the TIM layer comprises a liquid state metal material;
placing a lid structure on the adhesive layer and the TIM layer, wherein the lid structure comprises a trench on a bottom surface thereof; and
attaching the lid structure to the substrate and the package structure through the adhesive layer and the TIM layer.

19. The method of claim 18, wherein attaching the lid structure to the substrate and the package structure comprises:
pressing the lid structure against the adhesive layer and the TIM layer such that at least a portion of the TIM layer flows into the trench of the lid structure; and
curing the adhesive layer and the TIM layer such that the lid structure is attached to the substrate and the package structure respectively through the adhesive layer and the TIM layer.

20. The method of claim 19, wherein the liquid state metal material of the TIM layer is in a liquid state before and after curing.
